(19) United States
(12) Patent Application Publication
(10) Pub. No.: US 2026/0246131 A1
(43) Pub. Date: Aug. 20, 2026

(54) WAVEGUIDE STRUCTURES SEMICONDUCTOR PACKAGE INCLUDING THE SAME

(71) Applicant: Samsung Electronics Co., Ltd., Suwon-si (KR)

(72) Inventors: Seungyoon JUNG, Suwon-si (KR); Won Cheol Lee, Suwon-si (KR); Seongjung Kim, Suwon-si (KR); Youngki Lee, Suwon-si (KR); Dongkwon Choi, Suwon-si (KR)

(73) Assignee: Samsung Electronics Co., Ltd., Suwon-si (KR)

(21) Appl. No.: 19/307,186

(22) Filed: Aug. 22, 2025

(30) Foreign Application Priority Data
Feb. 20, 2025 (KR) 10-2025-0022545

(51) Int. Cl. H01P 3/08; H01L 23/66

(52) U.S. Cl. CPC H01P 3/08; H10W 44/20; H10W 44/216

(57) ABSTRACT

According to at least one example embodiment, a waveguide structure comprising: a first substrate; a first wiring positioned on the first substrate; a second wiring positioned apart from the first wiring and opposing the first wiring; and a plurality of solder patterns positioned between the first wiring and the second wiring, arranged spaced apart from each other in the first direction, and defining a waveguide region extending along the first direction between the first wiring and the second wiring.

### CROSS-REFERENCE TO RELATED APPLICATION

This application claims priority to and the benefit of Korean Patent Application No. 10-2025-0022545 filed with the Korean Intellectual Property Office on Feb. 20, 2025, the entire contents of which are incorporated herein by reference.

### BACKGROUND

### 1. Field

The described technology relates generally to a waveguide structure and a semiconductor package including the same.

### 2. Description of the Related Art

With the development of Information Technology (IT), various types of semiconductor devices such as smartphones and tablet personal computers (PCs) are becoming widely distributed. The semiconductor devices may wirelessly communicate with other semiconductor devices and/or a base station using an antenna module.

Due to the recent rapid increase in network traffic caused by semiconductor devices, fifth generation mobile communication technologies such as 5G (5th Generation) NR (New Radio) technology and 6G (6th Generation) technology are being developed. 5G technology uses FR1 (Frequency Range 1) and FR2 frequency bands, of which FR2 is defined as a frequency band above about 6 GHz, and specifically includes the millimeter wave (mmWave) band (about 24 GHz to 100 GHz).

### SUMMARY

According to example embodiments, loss of an RF signal transmission of a waveguide structure and a semiconductor package including the same may be improved, and reliability may be enhanced.

According to example embodiments, a waveguide structure comprising: a first substrate; a first wiring on the first substrate; a second wiring spaced apart from first substrate and the first wiring such that the second wiring is opposing the first wiring; and a plurality of solder patterns between the first wiring and the second wiring, the plurality of solder patterns spaced apart from each other in a first direction, and defining a waveguide region between the first wiring and the second wiring such that the waveguide region extends along the first direction.

According to example embodiments, a waveguide structure comprising: a first substrate; a first wiring on the first substrate, the first wiring extending in a first direction; a second wiring spaced apart from the first substrate and the first wiring, the second wiring extending in the first direction and opposing the first wiring; and a plurality of solder patterns electrically connected to the first wiring and the second wiring and spaced apart from each other in the first direction and in a second direction intersecting the first direction such that the plurality of solder patterns define a waveguide region extending along the first direction between the first wiring and the second wiring.

According to example embodiments, a semiconductor package comprising: a first substrate, an interconnector the first substrate and configured to receive an RF signal, an integrated circuit mounted on the first substrate and spaced apart from the interconnector in a first direction, a waveguide structure configured to transmit the RF signal from the interconnector and to the integrated circuit; a semiconductor chip mounted on the first substrate and spaced apart from the waveguide structure. The waveguide structure includes a first wiring on the first substrate, a second wiring spaced apart from the first wiring, and a plurality of solder patterns between the first wiring and the second wiring, the plurality of solder patterns spaced apart from each other in the first direction, and defining a waveguide region between the first wiring and the second wiring such that the waveguide region extends along the first direction.

According to embodiments, loss of the RF signal transmission may be improved and reliability may be enhanced.

### BRIEF DESCRIPTION OF THE DRAWINGS

FIG. 1 is a perspective view showing a waveguide structure according to at least one example embodiment.

FIG. 2 is an exploded perspective view showing a waveguide structure according to at least one example embodiment.

FIG. 3 is a plan view showing a waveguide structure according to at least one example embodiment.

FIG. 4 is a cross-sectional view taken along line A-A′ of FIG. 3.

FIGS. 5 to 8 are cross-sectional views corresponding to A-A′ of FIG. 3, illustrating a waveguide structure according to some example embodiments.

FIG. 9 is a plan view showing a waveguide structure according to some example embodiments.

FIG. 10 is a cross-sectional view taken along line B-B′ of FIG. 9.

FIG. 11 is a plan view showing a waveguide structure according to some example embodiments.

FIGS. 12 to 14 are cross-sectional views illustrating a semiconductor package including a waveguide structure according to at least one example embodiment.

FIG. 15 is a block diagram of an electronic device according to at least one example embodiment.

### DETAILED DESCRIPTION

Hereinafter, various embodiments will be described in detail with reference to the attached drawings so that a person having ordinary skill in the art to which the present invention pertains may easily implement the invention. The present invention may be embodied in many different forms and is not limited to the embodiments described herein.

In order to clearly explain the present invention, parts irrelevant to the description are omitted, and the same reference numerals are used for identical or similar components throughout the specification.

In addition, the size and the thickness of each component shown in the drawing are arbitrarily shown for convenience of explanation, so the present invention is not necessarily limited to what is shown. To clearly represent the various layers and areas in the drawing, the thickness is enlarged and shown. And in the drawing, for convenience of explanation, the thickness of some layers and areas is exaggerated. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Also, when we say that a part, such as a layer, membrane, region, or plate, is “over” or “on” another part, this includes not only cases where it is “directly over” the other part, but also cases where there are other parts in between. Conversely, when we say that a part is “directly above” another part, we mean that there is no other part in between. Also, being “above” or “on” a reference part means being located above or below the reference part, and does not necessarily mean being located “above” or “on” the opposite direction of gravity. More specifically, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Additionally, throughout the specification, whenever a part is said to “include” a component, this does not mean that it excludes other components, but rather that it may include other components, unless otherwise specifically stated.

Additionally, the use of term herein, such as “unit” or “module”, to indicate a functional unit configured to process at least one function or operation may be implemented in and/or by processing circuitry, such as hardware, software, or in a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., unless expressly indicated otherwise. The processing circuitry may include electrical components such as at least one of transistors, resistors, capacitors, etc., and/or electronic circuits including said components. Also, connecting lines or connecting members illustrated in the drawings are intended to represent example functional relationships and/or physical or logical connections between the various elements. It should be noted that many alternative or additional functional relationships, physical connections or logical connections may be present in a practical device.

Additionally, throughout the specification, “in plan” represents when the target portion is viewed from above, and “in cross section” represents when the target portion is viewed from the side in a cross-section cut vertically.

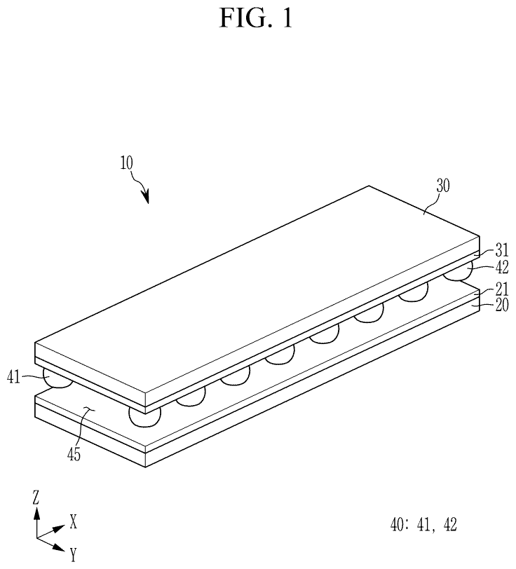

Hereinafter, a waveguide structure according to at least one example embodiment will be described with reference to FIGS. 1 to 4.

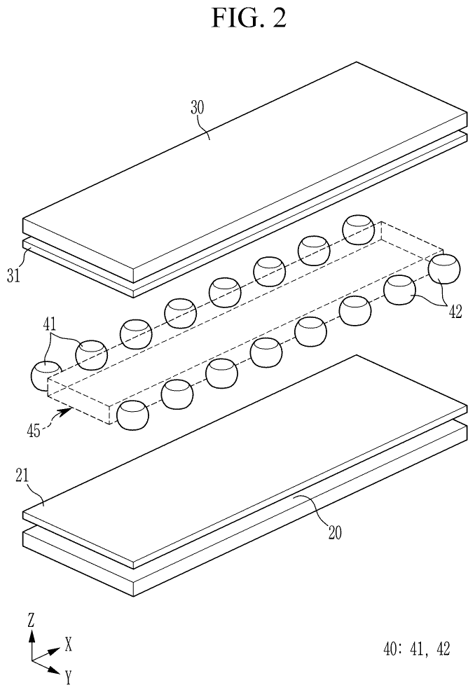

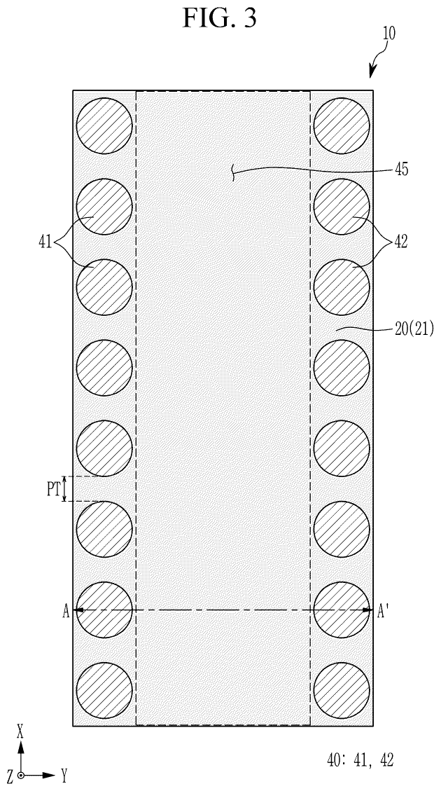

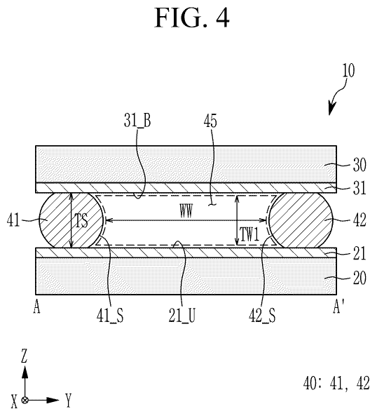

FIG. 1 is a perspective view showing a waveguide structure according to at least one example embodiment. FIG. 2 is an exploded perspective view showing a waveguide structure according to at least one example embodiment. FIG. 3 is a plan view showing a waveguide structure according to at least one example embodiment. FIG. 4 is a cross-sectional view taken along line A-A′ of FIG. 3.

Referring to FIGS. 1 to 4, a waveguide structure 10 according to at least one example embodiment is a structure that is configured to transmit a radio frequency (RF) signal. For example, the waveguide structure 10 according to at least one example embodiment may transmit the RF signal having a millimeter wave (mmWave) band (about 24 gigahertz (GHz) to about 100 GHz), but the example embodiments are not limited thereto. As another example, the waveguide structure 10 may transmit the RF signal having a frequency band of about 100 GHz or greater. As another example, the waveguide structure 10 may also transmit the RF signal having a frequency band of about 24 GHz or less (e.g., long-term evolution (LTE) signals, etc.). The waveguide structure 10 may serve as a medium for receiving RF signals from the outside and/or for transmitting RF signals to the outside. For example, the waveguide structure 10 may transmit the RF signal transmitted from a radio frequency integrated circuit (RFIC), a communication processor (CP), an antenna, etc. to a surrounding element, but example embodiments are not limited thereto. In at least one example embodiment, the RF signal may have a frequency of about 24 GHz to about 100 GHz. As another example, the RF signal may be a long-term evolution (LTE) signal having a frequency band of about 700 MHz, but example embodiments are not limited thereto.

A waveguide structure 10 according to at least one example embodiment may include a first substrate 20, a first wiring 21 positioned on the first substrate 20, a second wiring 31 positioned spaced apart from the first wiring 21, and a plurality of solder patterns 40 defining a waveguide region 45 positioned between the first wiring 21 and the second wiring 31 and extending in one direction between the first wiring 21 and the second wiring.

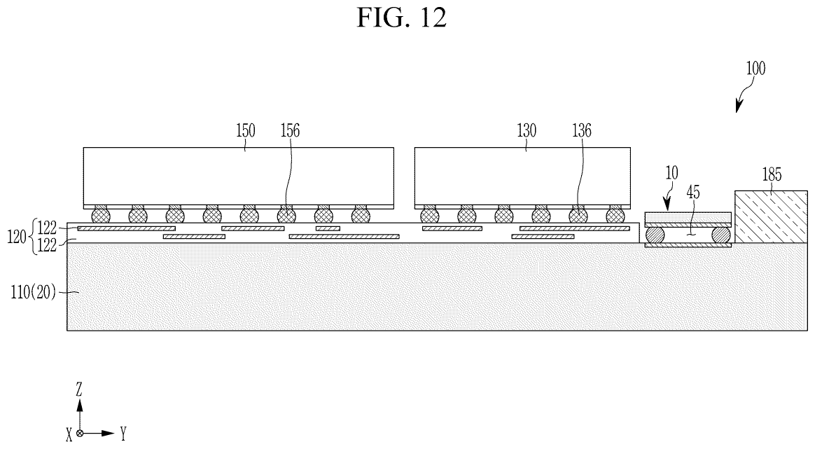

The first substrate 20 may be a substrate for a package, for example, a printed circuit board (PCB), a ceramic substrate, and/or the like. If the first substrate 20 is a printed circuit board, the first substrate 20 may be made of, for example, at least one material selected from phenol resin, epoxy resin, and polyimide. In at least one example embodiment, the first substrate 20 may include integrated circuits. The first substrate 20 may include one or more routing wires. As an example, the first substrate 20 may be configured as at least a portion of a package substrate (see 110 of FIG. 12) on which an optical integrated circuit (see 130 of FIG. 12) and/or a semiconductor chip (see 150 of FIG. 12) is mounted. As another example, the first substrate 20 may comprise at least a portion of a redistribution structure (see 120 of FIG. 12) positioned over the package substrate. As another example, the first substrate 20 may be a dummy substrate made of and/or including an electrically conductive material (herein also referred to as a conductive material) and/or an insulating film.

The first substrate 20 may include upper surface and lower surface that are opposed to each other. The upper surface and lower surface of the first substrate 20 may be formed as planes parallel to a first direction (e.g., the X direction) and a second direction (e.g., Y direction) intersecting the first direction (X direction). The first and second directions may also be respectively referred to as a first horizontal direction and a second horizontal direction. The upper surface of the first substrate 20 may be a surface opposite to the lower surface in a third direction (e.g., Z direction). Here, the third direction (Z direction) may also be referred to a vertical direction and may be perpendicular to the upper surface of the first substrate 20.

The first wiring 21 may be positioned on first substrate 20. The first wiring 21 may be positioned on the upper surface of the first substrate 20. The first wiring 21 may be extended in the first direction (X direction). For example, the first wiring 21 may extend in substantially the same direction as the waveguide region 45, which will be described later. The first wiring 21 may have an upper surface 21_U and a lower surface. The lower surface of the first wiring 21 may face and/or be in contact with the first substrate 20, and the upper surface 21_U of the first wiring 21 may form the lower surface of the waveguide region 45 to be described later. In at least one example embodiment, a predetermined voltage may be applied to the first wiring 21. For example, the first wiring 21 may be subjected to a ground voltage. The first wiring 21 may be electrically connected to the first substrate 20, but the example embodiments are not limited thereto.

The first wiring 21 may include a conductive material. For example, the first wiring 21 may include a metal material including, for example, at least one of copper (Cu), aluminum (Al), silver (Ag), tin (Sn), gold (Au), nickel (Ni), lead (Pb), titanium (Ti), an alloy thereof, and/or the like.

In FIGS. 1 to 4, the first wiring 21 is depicted as being formed as a single layer, but the example embodiments are not limited thereto. For example, the first wiring 21 may be made of multiple layers. For example, the first wiring 21 may comprise a stack of metal layers. Additionally, in some example embodiments, the first wiring 21 may be configured as part of the routing wiring included in the first substrate 20.

The waveguide structure 10 according to at least one example embodiment may further include a second substrate 30 positioned over the first wiring 21.

The second substrate 30 may be positioned over the first wiring 21. The second substrate 30 may be positioned over the first substrate 20. The second substrate 30 may be positioned to be spaced apart from the first substrate 20 in the third direction (Z direction). At least a portion of the second substrate 30 may overlap the first substrate 20 in the third direction (Z direction).

The second substrate 30 may be a substrate for a package, for example, a printed circuit board (PCB), a ceramic substrate, and/or the like. If the second substrate 30 is a printed circuit board, the second substrate 30 may be made of at least one material selected from phenol resin, epoxy resin, and polyimide. In at least one example embodiment, the second substrate 30 may include integrated circuits. The second substrate 30 may include one or more routing wires. For example, the second substrate 30 may be a dummy substrate made of and/or including a conductive material and/or an insulating film. As another example, the second substrate 30 may comprise at least a portion of a substrate forming an optical integrated circuit (see 130 of FIG. 12).

The second wiring 31 may be positioned on and/or over the first wiring 21. The second wiring 31 may be spaced apart from the first wiring 21 in the third direction (Z direction). The second wiring 31 may be positioned on the lower surface of the second substrate 30. The second wiring 31 may be positioned between the first wiring 21 and the second board 30. The second wiring 31 may be opposite the first wiring 21. The second wiring 31 may have a lower surface 31_B and an upper surface opposite to the upper surface 21_U of the first wiring 21. The upper surface of the second wiring 31 may face and/or be in contact with the second substrate 30. The lower surface 31_B of the second wiring 31 may form the upper surface of the waveguide region 45, which will be described later.

The second wiring 31 may be extended in the first direction (X direction). The second wiring 31 may be extended parallel to the first wiring 21. The second wiring 31 may extend in the same and/or a substantially similar direction as the waveguide region 45, which will be described later.

In at least one example embodiment, a predetermined voltage may be applied to the second wiring 31. For example, the second wiring 31 may be subjected to ground voltage. The second wiring 31 may be electrically connected to the second substrate 30, but example embodiments are not limited thereto. In at least one example embodiment, the second wiring 31 may be electrically connected to the first wiring 21. For example, the second wiring 31 may be electrically connected to the first wiring 21 through the plurality of solder patterns 40 described later, but example embodiments are not limited thereto. For example, the second wiring 31 may be electrically connected to a separate wire to which ground voltage is applied.

The second wiring 31 may include a conductive material. The second wiring 31 may include the same and/or a substantially similar material as the first wiring 21, but example embodiments are not limited thereto. For example, the second wiring 31 may include a metal material including, for example, at least one of copper (Cu), aluminum (Al), silver (Ag), tin (Sn), gold (Au), nickel (Ni), lead (Pb), titanium (Ti), an alloy thereof, and/or the like. For example, in at least one example embodiment, the first wiring 21 and the second wiring 31 may each include a conductive material; and the conductive material of the first wiring layer 21 may be the same and/or different to the conductive material of the second wiring layer 31.

In FIGS. 1 to 4, the second wiring 31 is depicted as being formed as a single layer, but example embodiments are not limited thereto. For example, the second wiring 31 may be made of multiple layers. Additionally, in some example embodiments, the second wiring 31 may be configured as part of a routing wiring comprised by the second substrate 30.

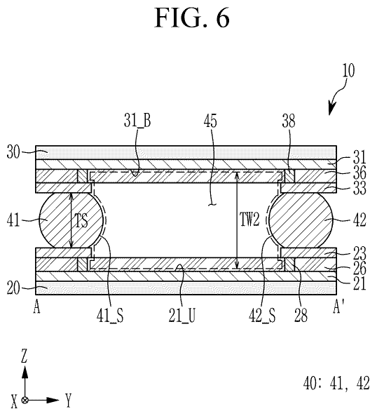

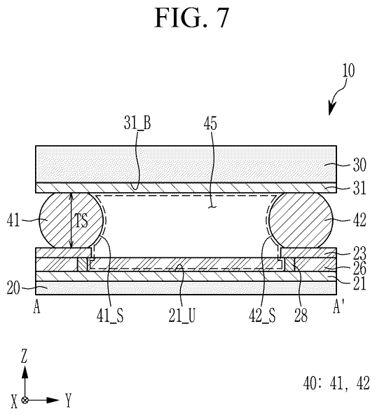

The plurality of solder patterns 40 may be positioned between the first wiring 21 and the second wiring 31. The plurality of solder patterns 40 may be positioned between the first substrate 20 and the second substrate 30. The plurality of solder patterns 40 may be in contact with the upper surface 21_U of the first wiring 21, and may be in contact with the lower surface 31_B of the second wiring 31. However, this is not limited to the above, and additional conductive layers may be positioned between the plurality of solder patterns 40 and the first wiring 21 and between the plurality of solder patterns 40 and the second wiring 31. A description of this is given in FIGS. 6 and 7, as described below.

In at least one example embodiment, a plurality of solder patterns 40 may be arranged spaced apart from each other in the first direction (X direction) and the second direction (Y direction) intersecting the first direction (X direction) between the first wiring 21 and the second wiring 31. In these cases, the spacing PT between the plurality of solder patterns 40 spaced apart in the first direction (X direction) may be smaller than the width between the plurality of solder patterns 40 spaced apart in the second direction (Y direction). In at least one example embodiment, a plurality of solder patterns 40 may define a waveguide region 45. The waveguide region 45 may be defined by the side surface of a plurality of solder patterns 40 adjacent in the second direction (Y direction). A first group (the first solder patterns 41) and a second group (the second solder patterns 42) of the plurality of solder patterns 40 may. respectively, define opposite sides of the waveguide region 45. A detailed explanation of this will be given later in the description of waveguide region 45.

In at least one example embodiment, the plurality of solder patterns 40 may have a truncated spherical shape. For example, the upper surface and lower surface of the plurality of solder patterns 40 may be flat, and the plurality of solder patterns 40 may have a jar shape in a cross-section formed in the second direction (Y direction) and the third direction (Z direction). That is, the width of the plurality of solder patterns 40 in the second direction (Y direction) may increase and then decrease as it gets farther away from the upper surface 21_U of the first wiring 21. In at least one example embodiment, the side surfaces of the plurality of solder patterns 40 may include curved surfaces. As illustrated in FIG. 2, on a plane comprising of the first direction (X direction) and the second direction (Y direction), a plurality of solder patterns 40 may have a circular shape. However, the example embodiments are not limited thereto, and the shapes of the plurality of solder patterns 40 may be changed in various ways.

In at least one example embodiment, the thickness TS of the plurality of solder patterns 40 along the third direction (Z direction) may be smaller than the width of the plurality of solder patterns 40 along the second direction (Y direction). Here, the width of the plurality of solder patterns 40 in the second direction (Y direction) may refer to the diameter of the plurality of solder patterns 40 on a plane. For example, the ratio of the thickness TS of the plurality of solder patterns 40 along the third direction (Z direction) to the width of the plurality of solder patterns 40 along the second direction (Y direction) may be about ½, but example embodiments are not limited thereto. In this range, the RF signal may be relatively easily transmitted into the space between plurality of solder patterns 40, and noise signals may be easily blocked during the transmission of RF signals. Here, the RF signal may have a millimeter wave (mmWave) band (about 24 GHz to about 100 GHz). Alternatively, the RF signal may have a frequency band greater than about 100 GHz, or a frequency band less than about 24 GHz (e.g., a long-term evolution (LTE) signal). An explanation of this will be given later in the explanation of the waveguide region 45.

A plurality of solder patterns 40 may be electrically connected to the first wiring 21 and the second wiring 31. In at least one example embodiment, a predetermined voltage may be applied to a plurality of solder patterns 40. For example, a ground voltage may be applied to the plurality of solder patterns 40.

The plurality of solder patterns 40 may include a conductive material. For example, the plurality of solder patterns 40 may include a solder including at least one of tin (Sn), silver (Ag), copper (Cu), manganese (Mn), lead (Pb), and/or alloys thereof. The plurality of solder patterns 40 may include, for example, solder balls and solder bumps.

A plurality of solder patterns 40 of the waveguide structure 10 according to at least one example embodiment may include a plurality of first solder patterns 41 and a plurality of second solder patterns 42 arranged spaced apart from each other in the first direction (X direction).

The plurality of first solder patterns 41 and the plurality of second solder patterns 42 may be arranged spaced apart from each other along the first direction (X direction). The plurality of first solder patterns 41 and the plurality of second solder patterns 42 may extend in a direction parallel to the first wiring 21 and the second wiring 31. In these cases, the spacing PT between the plurality of first solder patterns 41 along the first direction (X direction) may be set to correspond to the guided wavelength of the RF signal transmitted into the waveguide region 45 to be described later. For example, the spacing PT between the plurality of first solder patterns 41 along the first direction (X direction) may be less than or equal to half the guided wavelength of the RF signal transmitted into the waveguide region 45, which will be described later. The spacing PT between the plurality of first solder patterns 41 along the first direction (X direction) may be greater than about 0 mm and less than or equal to about 8 mm. In at least one example, the spacing PT between the plurality of first solder patterns 41 along the first direction (X direction) may be greater than 0 mm and less than or equal to about 1.95 mm. In this range, transmission loss of the RF signal applied within the waveguide region 45 may be protected against (e.g., prevented and/or reduced). Here, the spacing PT between the plurality of first solder patterns 41 along the first direction (X direction) may refer to the minimum length along the first direction (X direction) between the plurality of adjacent first solder patterns 41 along the first direction (X direction). As described in further detail below, the RF signal may have millimeter wave (mmWave) bands (about 24 GHz to about 100 GHz). Alternatively, the RF signal may have a frequency band greater than about 100 GHz, or a frequency band less than about 24 GHz (e.g., a long-term evolution (LTE) signal). In at least one example embodiment, the spacing PT between the plurality of first solder patterns 41 along the first direction (X direction) may be varied depending on the signal characteristics transmitted within the waveguide region 45, which will be described later.

In at least one example embodiment, the spacing PT between the plurality of second solder patterns 42 along the first direction (X direction) may be substantially equal to the spacing PT between the plurality of first solder patterns 41 along the first direction (X direction), but example embodiments are not limited thereto. The spacing PT between the plurality of second solder patterns 42 along the first direction (X direction) may be set to correspond to the guided wavelength of the RF signal transmitted into the waveguide region 45, which will be described later. For example, the spacing PT between the plurality of second solder patterns 42 along the first direction (X direction) may be less than or equal to half the guided wavelength of the RF signal transmitted into the waveguide region 45, which will be described later. The spacing PT between the plurality of second solder patterns 42 along the first direction (X direction) may be greater than 0 mm and less than or equal to about 1.95 millimeters (mm). Here, the spacing PT between the plurality of second solder patterns 42 along the first direction (X direction) may refer to the minimum length along the first direction (X direction) between the plurality of adjacent second solder patterns 42 along the first direction (X direction). In at least one example embodiment, the spacing PT between the plurality of second solder patterns 42 along the first direction (X direction) may be varied depending on the signal characteristics transmitted within the waveguide region 45, which will be described later.

In at least one example embodiment, a plurality of first solder patterns 41 and the plurality of second solder patterns 42 may be positioned spaced apart along the second direction (Y direction). The distance between the plurality of first solder patterns 41 and the plurality of second solder patterns 42 in the second direction (Y direction) may be greater than or equal to the distance between the first wiring 21 and the second wiring 31. The distance between the plurality of first solder patterns 41 and the plurality of second solder patterns 42 in the second direction (Y direction) may be greater than or equal to the thickness TS along the third direction (Z direction) of the plurality of solder patterns 40. The distance between the plurality of first solder patterns 41 and the plurality of second solder patterns 42 in the second direction (Y direction) may be less than 10 mm. In at least one example embodiment, the distance between the plurality of first solder patterns 41 and the plurality of second solder patterns 42 in the second direction (Y direction) may be about 2.5 mm or less. In this range, noise signals having a different frequency band from the RF signal may be blocked. In other words, the frequency band of the RF signal may be selected based on the distance (WW) between the first solder patterns 41 and the second solder patterns 42 in the second direction (Y direction) and the height (TW1) of the waveguide region 45. Here, the distance between the plurality of first solder patterns 41 and the plurality of second solder patterns 42 along the second direction (Y direction) may refer to the minimum distance between the first solder pattern and the second solder pattern that are positioned spaced apart in the second direction (Y direction). The RF signal may have millimeter wave (mmWave) bands (about 24 GHz to about 100 GHz). Alternatively, the RF signal may have a frequency band greater than about 100 GHz, or a frequency band less than about 24 GHz (e.g., a long-term evolution (LTE) signal). In at least one example embodiment, the distance between the plurality of first solder patterns 41 and the plurality of second solder patterns 42 along the second direction (Y direction) may vary depending on the signal characteristics transmitted within the waveguide region 45, which will be described later.

The plurality of first solder patterns 41 and the plurality of second solder patterns 42 of a waveguide structure 10 according to at least one example embodiment may define a waveguide region 45. For example, the waveguide structure 10 according to at least one example embodiment may include a void space between the first wiring 21 and the second wiring 31, and between the plurality of first solder patterns 41 and the plurality of second solder patterns 42, and the void space between the plurality of first solder patterns 41 and the plurality of second solder patterns 42 may be defined as a waveguide region 45. The waveguide region 45 may refer to a space defined by (e.g., surrounded by) the upper surface of the first substrate 20, the lower surface of the second substrate 30, one side surface 41_S of the plurality of first solder patterns 41, and one side surface 42_S of the plurality of second solder patterns 42. The waveguide region 45 may be surrounded by the first wiring 21, a second wiring 31, a plurality of first solder patterns 41, and a plurality of second solder patterns 42.

In at least one example embodiment, the waveguide region 45 may extend in the first direction (X direction). This is because the waveguide region 45 is defined by the first wiring 21 and the second wiring 31 extending in the first direction (X direction) and the plurality of first solder patterns 41 and the plurality of second solder patterns 42 arranged spaced apart from each other in the first direction (X direction).

Specifically, the plurality of first solder patterns 41 and the plurality of second solder patterns 42 may define a waveguide region 45. The waveguide region 45 may be positioned between the plurality of first solder patterns 41 and the plurality of second solder patterns 42. One side surface 41_S of the plurality of first solder patterns 41 and one side surface 42_S of the plurality of second solder patterns 42 may define opposite sides of the waveguide region 45. In these cases, one side surface 41_S of the plurality of first solder patterns 41 and one side surface 42_S of the plurality of second solder patterns 42 may be opposite each other along the second direction (Y direction). The two side surfaces of the waveguide region 45 may include curved surfaces, but the example embodiments are not limited thereto.

Additionally, waveguide region 45 may be positioned between the first wiring 21 and the second wiring 31. The waveguide region 45 may be defined by the first wiring 21 and the second wiring 31. For example, the upper surface 21_U of the first wiring 21 may define the lower surface of the waveguide region 45. The lower surface 31_B of the second wiring 31 may define the upper surface of the waveguide region 45. In these cases, the upper surface 21_U of the first wiring 21 and the lower surface 31_B of the second wiring 31 may be surfaces opposing each other along the first direction (X direction).

In at least one example embodiment, the waveguide region 45 is configured to transmit the RF signal. For example, the waveguide region 45 may serve as a medium for receiving RF signals from the outside or transmitting RF signals to the outside. The RF signal incident within the waveguide region 45 is totally reflected by the first wiring 21 and the second wiring 31 extending in the first direction (X direction) and the plurality of first solder patterns 41 and the plurality of second solder patterns 42 arranged spaced apart from each other in the first direction (X direction), thereby implementing a signal path extending along the first direction (X direction). Here, the RF signal may have a frequency of about 24 GHz to about 100 GHz, but example embodiments are not limited thereto. As another example, the RF signal may have a frequency band greater than about 100 GHz, or a frequency band less than about 24 GHz (e.g., a long-term evolution (LTE) signal).

In at least one example embodiment, the waveguide region 45 may have a width WW along the second direction (Y direction) and a first height TW1 along the third direction (Z direction). The width WW of the waveguide region 45 in the second direction (Y direction) and the first height TW1 of the waveguide region 45 in the third direction (Z direction) may be set to correspond to the guided wavelength of the RF signal transmitted into the waveguide region 45. The width WW of the waveguide region 45 along the second direction (Y direction) may be greater than or equal to the distance (TW1) between the first wiring 21 and the second wiring 31. Additionally, the width WW of the waveguide region 45 in the second direction (Y direction) may be greater than or equal to the thickness TS of the plurality of solder patterns 40 in the third direction (Z direction). For example, the width WW of the waveguide region 45 along the second direction (Y direction) may be less than about 2.5 mm. In this range, noise signals having a different frequency band from the RF signal may be blocked. Here, the width WW of the waveguide region 45 in the second direction (Y direction) may be determined by the distance between the plurality of first solder patterns 41 and the plurality of second solder patterns 42 in the second direction (Y direction). Additionally, the width WW of the waveguide region 45 in the second direction (Y direction) may be greater than or equal to the first height TW1 of the waveguide region 45 in the third direction (Z direction). For example, the ratio of the first height TW1 along the third direction (Z direction) of the waveguide region 45 to the width WW of the waveguide region 45 along the second direction (Y direction) may be about ½, but example embodiments are not limited thereto. In this range, the RF signal may be easily transmitted, and noise signals may be easily blocked during the transmission of the RF signal. Here, the first height TW1 along the third direction (Z direction) of the waveguide region 45 may be determined by the thickness TS along the third direction (Z direction) of the plurality of solder patterns 40 and/or the distance along the third direction (Z direction) between the first wiring 21 and the second wiring 31. The RF signal may have millimeter wave (mmWave) bands (about 24 GHz to about 100 GHz). Alternatively, the RF signal may have a frequency band greater than about 100 GHz, or a frequency band less than about 24 GHz (e.g., a long-term evolution (LTE) signal).

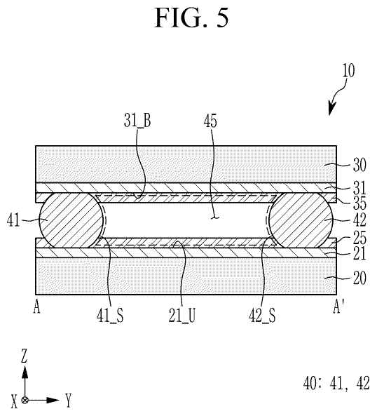

In at least one example embodiment, the waveguide region 45 may comprise air. The waveguide region 45 may be an air gap region. In these cases, since the permittivity of air is approximately 1, the permittivity of the waveguide region 45 may be approximately 1. Accordingly, transmission loss of the RF signal applied within the waveguide region 45 may be prevented. However, the example embodiments are not limited thereto, and the waveguide region 45 may further include an insulating film and/or a dielectric layer having a different permittivity from air. As another example, the waveguide region 45 may be filled with an underfill film or the like. A description of this will be given later in FIGS. 5 to 8.

The spacing PT between a plurality of solder patterns 40 defining a waveguide region 45 of the waveguide structure 10 in the first direction (X direction) according to at least one example embodiment may be set to correspond to a guided wavelength of the RF signal transmitted into the waveguide region 45. For example, the spacing PT between plurality of solder patterns 40 defining a waveguide region 45 along the first direction (X direction) may be less than or equal to half the guided wavelength of the RF signal. In this range, the RF signal may be totally reflected by the plurality of solder patterns 40 and transmitted to the surrounding components. Additionally, the waveguide region 45 through which the RF signal is transmitted may be an air gap region defined by the first wiring 21, the second wiring 31, and the plurality of solder patterns 40. Accordingly, the waveguide region 45 according to at least one example embodiment may have a low permittivity, and thus, the transmission loss of the RF signal may be improved.

Additionally, a distance between the plurality of first solder patterns 41 and the plurality of second solder patterns 42 along the second direction (Y direction) defining the width WW of the waveguide region 45 along the second direction (Y direction) may be set to correspond to a guided wavelength of the RF signal transmitted into the waveguide region 45. For example, the distance between the plurality of first solder patterns 41 and the plurality of second solder patterns 42 in the second direction (Y direction) may be about 2.5 mm or less. In this range, noise signals having a different frequency band from the RF signal having the mmWave may be effectively blocked.

Accordingly, the waveguide structure 10 according to at least one example embodiment may easily design the arrangement, size, and spacing of the plurality of solder patterns 40 according to the band of the RF signal to be transmitted. In addition, the waveguide structure 10 according to at least one example embodiment may reduce the transmission loss of the RF signal and enhance reliability of the RF signal transmission.

Hereinafter, referring to FIGS. 5 to 11, waveguide structures according to some example embodiments will be described.

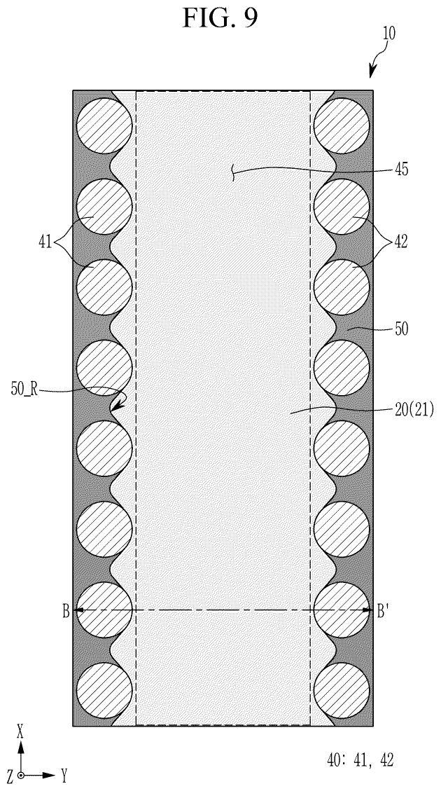

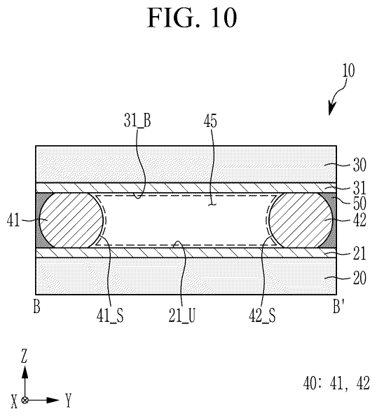

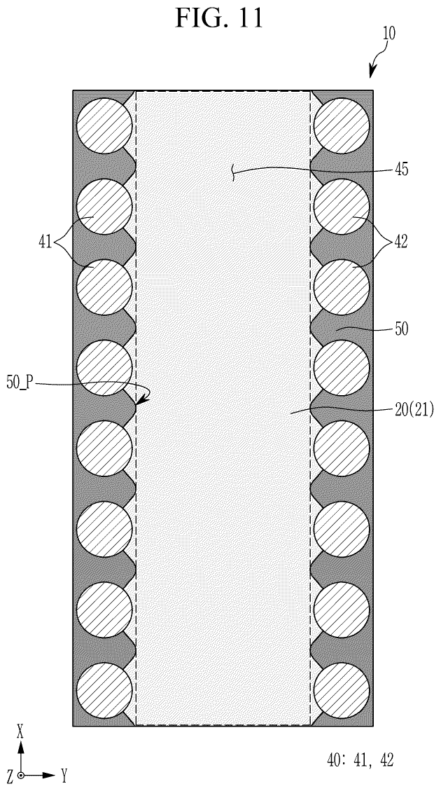

FIGS. 5 to 8 are cross-sectional views corresponding to A-A′ of FIG. 3, illustrating a waveguide structure according to some embodiments. FIG. 9 is a plan view showing a waveguide structure according to some embodiments. FIG. 10 is a cross-sectional view taken along line B-B′ of FIG. 9. FIG. 11 is a plan view showing a waveguide structure according to some embodiments.

The components illustrated in FIGS. 5 to 11 which share the same reference number as the components discussed above may be the same as (or substantially similar to) the components illustrated in FIGS. 1 to 4, so a description thereof will be omitted and the differences will be mainly explained.

Referring to FIG. 5, the waveguide structure 10 according to some example embodiments may further include a first insulating layer 25 positioned on an upper surface 21_U of the first wiring 21 and a second insulating layer 35 positioned on the lower surface 31_B of the second wiring 31.

The first insulation layer 25 may be positioned over the first wiring 21. The first insulating layer 25 may be positioned on the upper surface 21_U of the first wiring 21. The first insulating layer 25 may extend in the first direction (X direction) to cover the first wiring 21. The first insulating layer 25 may be spaced apart from the second wiring 31 along the third direction (Z direction). The first insulating layer 25 may protect against the routing wires of the first wiring 21 and/or the first substrate 20 from electrically connecting with other conductive materials.

In some example embodiments, the second insulating layer 35 may be positioned over the lower surface 31_B of the second wiring 31. The second insulating layer 35 may extend in the first direction (X direction) to cover the lower surface 31_B of the second wiring 31. The second insulating layer 35 may be spaced apart from the first wiring 21 along the third direction (Z direction). The second insulating layer 35 may protect against the routing wires of the second wiring 31 and/or the second substrate 30 from electrically connecting with other conductive materials.

In some example embodiments, the first insulating layer 25 and the second insulating layer 35 may include various insulating materials. For example, the first insulating layer 25 and the second insulating layer 35 may include solder resist, but example embodiments are not limited thereto. In these cases, the permittivity of the first insulating layer 25 and the second insulating layer 35 may be greater than the permittivity of air.

In some example embodiments, the plurality of solder patterns 40 may penetrate the first insulating layer 25 and be electrically connected to the first wiring 21. For example, the plurality of first solder patterns 41 and the plurality of second solder patterns 42 may penetrate the first insulating layer 25 and be electrically connected to the first wiring 21. A plurality of first solder patterns 41 and a plurality of second solder patterns 42 may penetrate the first insulating layer 25 and come into contact with the upper surface 21_U of the first wiring 21. Additionally, a plurality of solder patterns 40 may penetrate the second insulating layer 35 and be electrically connected to the second wiring 31. For example, a plurality of first solder patterns 41 and a plurality of second solder patterns 42 may be electrically connected to the second wiring 31 by penetrating the second insulating layer 35. A plurality of first solder patterns 41 and a plurality of second solder patterns 42 may penetrate the second insulating layer 35 and contact the lower surface 31_B of the second wiring 31.

Accordingly, the first insulating layer 25 and the second insulating layer 35 of the waveguide structure 10 according to some example embodiments may be positioned in at least a portion of the waveguide region 45. For example, the waveguide region 45 may include a first region comprising of an air gap region and a second region comprising of a first insulating layer 25 and the second insulating layer 35. The first region may be positioned at the center of the waveguide region 45, and the second region may be positioned at the upper side and lower side of the waveguide region 45. That is, a first insulating layer 25 may be positioned at the lower side of the waveguide region 45, and the second insulating layer 35 may be positioned at the upper side of the waveguide region 45. In some example embodiments, the RF signal may be transmitted through the first region and the second region of the waveguide region 45.

Referring to FIG. 6, the waveguide structure 10 according to some embodiments may further include a first dielectric layer 26 positioned over the first wiring 21, a first pad 23 positioned over the first dielectric layer 26, and a first via 28 positioned between the first pad 23 and the first wiring 21.

The first dielectric layer 26 may be positioned on top of the first wiring 21. The first dielectric layer 26 may be positioned on the upper surface 21_U of the first wiring 21. The first dielectric layer 26 may extend in the first direction (X direction) to cover the first wiring 21. The first dielectric layer 26 may be spaced apart from the second wiring 31 along the third direction (Z direction). The first dielectric layer 26 may include various insulating materials. The first dielectric layer 26 may include a material having a predetermined dielectric constant. For example, the first dielectric layer 26 may comprise a material having a permittivity greater than that of air. The first dielectric layer 26 may include a low-k and low-loss material.

The first pad 23 may be positioned on the first dielectric layer 26. The first pad 23 may be positioned between the first wiring 21 and the plurality of solder patterns 40. First pad 23 may overlap the plurality of solder patterns 40 in the third direction (Z direction). In some example embodiments, the first pad 23 may be positioned spaced apart from each other in the second direction (Y direction). For example, the first pad 23 may not be positioned within the waveguide region 45 defined by the plurality of first solder patterns 41 and the plurality of second solder patterns 42. The first pad 23 may be electrically connected to plurality of solder patterns 40. The first pad 23 may contact plurality of solder patterns 40. The first pad 23 may include a conductive material.

The first via 28 penetrates the first dielectric layer 26 to electrically connect the first pad 23 and the first wiring 21. The first via 28 may interface with first pad 23 and the first wiring 21. The first via 28 may include a conductive material.

The waveguide structure 10 according to some embodiments may further include a second dielectric layer 36 positioned on the lower surface 31_B of the second wiring 31, a second pad 33 positioned on a lower surface of the second dielectric layer 36, and a second via 38 positioned between the second pad 33 and the second wiring 31.

In some example embodiments, the second dielectric layer 36 may be positioned over the lower surface 31_B of the second wiring 31. The second dielectric layer 36 may extend in the first direction (X direction) to cover the lower surface 31_B of the second wiring 31. The second dielectric layer 36 may be spaced apart from the first wiring 21 along the third direction (Z direction). The second dielectric layer 36 may include a material having a predetermined dielectric constant. For example, the second dielectric layer 36 may include a material having a permittivity greater than that of air. The second dielectric layer 36 may include a low-k and low-loss material.

The second pad 33 may be positioned on the lower surface of the second dielectric layer 36. The second pad 33 may be positioned between the second wiring 31 and the plurality of solder patterns 40. The second pad 33 may overlap plurality of solder patterns 40 in the third direction (Z direction). In some example embodiments, the second pad 33 may be positioned spaced apart from each other in the second direction (Y direction). For example, the second pad 33 may not be positioned within the waveguide region 45 defined by the plurality of first solder patterns 41 and the plurality of second solder patterns 42. The second pad 33 may be electrically connected to plurality of solder patterns 40. The second pad 33 may contact plurality of solder patterns 40. The second pad 33 may include a conductive material.

The second via 38 penetrates the second dielectric layer 36 to electrically connect the second pad 33 and the second wiring 31. The second via 38 may interface with the second pad 33 and the second wiring 31. The second via 38 may include a conductive material.

In some example embodiments, the first pad 23 and the first via 28 are electrically connected to the first wiring 21, and the second pad 33 and the second via 38 are electrically connected to the second wiring 31, so that a ground voltage may be applied to the first pad 23, the first via 28, the second pad 33, and the second via 38.

In some example embodiments, first pad 23, first via 28, second pad 33, and second via 38 may define waveguide region 45. For example, the waveguide region 45 may be defined by the upper surface 21_U of the first wiring 21, the side surface of the first via 28, the side surface of the first pad 23, one side surface 41_S of the plurality of first solder patterns 41, the side surface of the second pad 33, the side surface of the second via 38, the lower surface 31_B of the second wiring 31, and one side surface 42_S of the plurality of second solder patterns 42. That is, the first wiring 21, the first via 28, the first pad 23, the plurality of first solder patterns 41, the second pad 33, the second via 38, the second wiring 31, and the plurality of second solder patterns 42 may surround the waveguide region 45.

In some example embodiments, the second height TW2 along the third direction (Z direction) of the waveguide region 45 may be greater than the thickness TS along the third direction (Z direction) of the plurality of solder patterns 40.

In some example embodiments, the first dielectric layer 26 and the second dielectric layer 36 may be positioned in at least a portion of the waveguide region 45. For example, the waveguide region 45 may include a third region comprising of an air gap region, a fourth region comprising of a portion of the first dielectric layer 26, and a portion of the second dielectric layer 36. The third region may be positioned at the center of the waveguide region 45, and the fourth region may be positioned at the upper side and lower side of the waveguide region 45. That is, the first dielectric layer 26 may be positioned at the lower side of the waveguide region 45, and the second dielectric layer 36 may be positioned at the upper side of the waveguide region 45. In some example embodiments, the RF signal may be transmitted through the third and fourth regions of waveguide region 45.

FIG. 6 illustrates the waveguide structure 10 further including a first dielectric layer 26 positioned on the first wiring 21, a first pad 23 positioned on the first dielectric layer 26, and the first via 28 positioned between the first pad 23 and the first wiring 21, a second dielectric layer 36 positioned on the lower surface 31_B of the second wiring 31, a second pad 33 positioned on a lower surface of the second dielectric layer 36, and the second via 38 positioned between the second pad 33 and the second wiring 31, but example embodiments are not limited thereto. For example, as illustrated in FIG. 7, the waveguide structure 10 according to some example embodiments may further include only a first dielectric layer 26 positioned over the first wiring 21, a first pad 23 positioned over the first dielectric layer 26, and the first via 28 positioned between the first pad 23 and the first wiring 21. In these cases, the plurality of solder patterns 40 may come into contact with the lower surface 31_B of the second wiring 31.

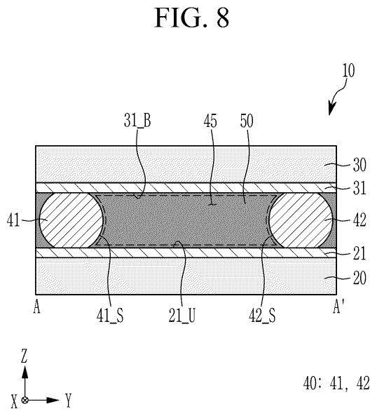

Referring to FIGS. 8 to 11, the waveguide structure 10 according to some embodiments may further include an underfill film 50 positioned between the first substrate 20 and the second substrate 30.

Referring to FIG. 8, the underfill film 50 may be provided in the gap area between the first substrate 20 and the second substrate 30. Underfill film 50 may be positioned between the first wiring 21 and the second wiring 31. The underfill film 50 may be in contact with the upper surface 21_U of the first wiring 21 and the lower surface 31_B of the second wiring 31, but example embodiments are not limited thereto. Underfill film 50 may cover the upper surface 21_U of the first wiring 21. The underfill film 50 may be positioned over the side surfaces of the plurality of solder patterns 40. The underfill film 50 may seal plurality of solder patterns 40.

In some example embodiments, the underfill film 50 may include a material having (and/or having had) flowability. For example, the underfill film 50 may include an insulating polymer, such as an epoxy-based polymer which has flowability prior to being set. In some example embodiments, the underfill film 50 may comprise a material having a higher dielectric constant than air. In some example embodiments, the underfill film 50 may include a material having a higher refractive index and/or density than air. The underfill film 50 may be formed by a capillary flow process after the second substrate 30 is mounted on the first substrate 20.

In some example embodiments, the underfill film 50 may be provided in the waveguide region 45. For example, the waveguide region 45 may be completely filled by the underfill film 50. However, the example embodiments are not limited thereto, and only a part of the waveguide region 45 may be filled with the underfill film 50. In some example embodiments, the RF signal may be transmitted through a portion of the underfill film 50 filled in the waveguide region 45.

Referring to FIGS. 9 to 11, the underfill film 50 of the waveguide structure 10 according to some example embodiments may not be provided in the waveguide region 45.

For example, in some example embodiments, the underfill film 50 may not be positioned on one side surface 41_S of the plurality of first solder patterns 41 and one side surface 42_S of the plurality of second solder patterns 42, but may be positioned on the other side surface of the plurality of first solder patterns 41 and the other side surface of the plurality of second solder patterns 42. Here, one side surface 41_S of the plurality of first solder patterns 41 and one side surface 42_S of the plurality of second solder patterns 42 may refer to a side surface of the plurality of solder patterns 40 defining opposite sides of the waveguide region 45. Accordingly, the underfill film 50 may surround at least a portion of the waveguide region 45, and the waveguide region 45 may be filled with air.

The underfill film 50 may be positioned between the plurality of first solder patterns 41 adjacent in the first direction (X direction) and between the plurality of second solder patterns 42 adjacent in the first direction (X direction), but example embodiments are not limited thereto. In these cases, as illustrated in FIG. 9, the underfill film 50 may include a recessed portion 50_R positioned between the plurality of first solder patterns 41 adjacent in the first direction (X direction) and between the plurality of second solder patterns 42 adjacent in the first direction (X direction). The recess 50_R may have a concave shape in the direction away from the waveguide region 45. However, the example embodiments are not limited thereto, and as another example, as illustrated in FIG. 11, the underfill film 50 may include a protrusion 50_P positioned between the plurality of first solder patterns 41 adjacent in the first direction (X direction) and between the plurality of second solder patterns 42 adjacent in the first direction (X direction). The protrusion 50_P may have a convex shape in the direction approaching the waveguide region 45.

In the example embodiments of FIGS. 9 to 11, the waveguide region 45 may be filled with air, and the underfill film 50 may surround at least a portion of the waveguide region 45. Since the underfill film 50 includes a material having a higher refractive index and/or higher density than air, the underfill film 50 may perform the function of a cladding layer for implementing a path of the RF signal, and the waveguide region 45 may perform the function of a core layer for implementing a path of the RF signal.

Hereinafter, a semiconductor package including a waveguide structure according to at least one example embodiment will be described, with reference to FIGS. 12 to 14.

FIGS. 12 to 14 are cross-sectional views illustrating a semiconductor package including a waveguide structure according to at least one example embodiment.

A semiconductor package 100 according to the embodiments of FIGS. 12 to 14 may include the waveguide structure 10 according to the embodiments of FIGS. 1 to 11. The waveguide structure 10 according to various example embodiments of the present disclosure described in the example embodiments of FIGS. 1 to 11 may be applied to the semiconductor package 100 according to the embodiments of FIGS. 12 to 14. The waveguide structure 10 may implement a signal transmission path between various components of the semiconductor package 100 according to the embodiments of FIGS. 12 to 14.

A semiconductor package 100 according to at least one example embodiment may include a package substrate 110, the waveguide structure 10 positioned on the package substrate 110, an interconnector 185 positioned on the package substrate 110 and configured to receive the RF signal, an integrated circuit 130 mounted on the package substrate 110, and a semiconductor chip 150 mounted on the package substrate 110.

The package substrate 110 may be a substrate for the package, for example, a printed circuit board (PCB) or a ceramic substrate. In at least one example embodiment, the package substrate 110 may include integrated circuits. The package substrate 110 may include one or more routing wires. In at least one example embodiment, the package substrate 110 may correspond to the first substrate 20 of the waveguide structure 10.

A semiconductor package 100 according to at least one example embodiment may further include a redistribution structure 120 positioned on a package substrate 110.

The redistribution structure 120 may be positioned on the package substrate 110. The redistribution structure 120 may be electrically connected to the routing wiring of the package substrate 110. In at least one example embodiment, the redistribution structure 120 may include a plurality of insulating layers 121, a plurality of redistribution layers 122, and a plurality of redistribution vias.

In at least one example embodiment, the plurality of redistribution layers 122 may be electrically connected to, and in direct contact with, routing wires disposed within the package substrate 110. In at least one example embodiment, the redistribution structure 120 may have a chip shape and be electrically connected to the package substrate 110 via bumps connected to a plurality of redistribution layers 122.

A plurality of insulating layers 121 may protect and insulate a plurality of redistribution layers 122. The plurality of insulating layers 121 may include an insulating resin. The insulating resin may include a thermosetting resin such as an epoxy resin, a thermoplastic resin such as a polyimide, or a resin impregnated with an inorganic filler and/or glass fiber (e.g., a photosensitive resin such as prepreg, ABF, FR-4, BT, or PID (Photo-Imageable Dielectric)). Depending on the process, the boundaries between the plurality of insulating layers 121 may be unclear and/or indistinct, but the example embodiments are not limited thereto.

A plurality of redistribution layers 122 may be electrically connected to the package substrate 110. For example, the plurality of redistribution layers 122 may be electrically connected to routing wires positioned within the package substrate 110. The plurality of redistribution layers 122 may be electrically connected to the semiconductor chip 150 and the integrated circuit 130, which will be described later. The plurality of redistribution layers 122 may also be referred as rewiring layers. The plurality of redistribution layers 122 may include a conductive material. The plurality of redistribution layers 122 may include a metallic material, for example, including copper (Cu), aluminum (Al), silver (Ag), tin (Sn), gold (Au), nickel (Ni), lead (Pb), titanium (Ti), or alloys thereof.

Interconnector 185 may be configured to receive signals applied from outside of semiconductor package 100. For example, interconnector 185 may be connected to an external cable and configured to receive a predetermined signal. As another example, interconnector 185 may be configured as an antenna module to receive a predetermined signal. Here, the predetermined signal may be the RF signal, but example embodiments are not limited thereto. Interconnector 185 may be of plug type or may be of wireless type including an antenna module. Interconnector 185 may function as an input/output port for signals between the external and semiconductor package 100. In at least one example embodiment, the interconnector 185 may be positioned on one side of the waveguide structure 10.

The semiconductor package 100 according to at least one example embodiment may further include a component (e.g., a radio frequency front end (RFFE)) that is configured to perform pre-processing on a signal received through interconnector 185, but the example embodiments are not limited thereto.

The integrated circuit 130 may be mounted on the package substrate 110. In at least one example embodiment, the integrated circuit 130 may be a radio frequency integrated circuit (RFIC), a photonic integrated circuit (PIC), and/or the like, but the example embodiments are not limited thereto. The integrated circuit 130 may receive the RF signal received through the waveguide structure 10.

In at least one example embodiment, the integrated circuit 130 may be connected to the package substrate 110 via solder 136. Solder 136 may include conductive materials. Solder 136 may include conductive materials. For example, solder 136 may include at least one of tin (Sn), silver (Ag), copper (Cu), manganese (Mn), lead (Pb), and/or alloys thereof. Solder 136 may include, for example, solder balls and solder bumps. In some example embodiments, the solder 136 may form the plurality of solder patterns 40 of the waveguide structure 10.

A semiconductor chip 150 may be mounted on a package substrate 110. A semiconductor chip 150 may be positioned on a redistribution structure 120 positioned on an upper surface of a package substrate 110. The semiconductor chip 150 may be positioned to be spaced apart from the waveguide structure 10. For example, the semiconductor chip 150 may be spaced apart from the first wiring 21 and the second wiring 31 of the waveguide structure 10. The semiconductor chip 150 may be electrically connected to the integrated circuit 130, but the example embodiments are not limited thereto. For example, the semiconductor chip 150 may be electrically connected to the integrated circuit 130 through the redistribution structure 120 In at least one example embodiment, the semiconductor chip 150 may be, but example embodiments are not limited thereto, an Application Specific Integrated Circuit (ASIC) chip. As another example, the semiconductor chip 150 may include at least one of a central processing unit (CPU), a graphic processing unit (GPU), memory, a controller, a codec, a sensor, and a communication chip.

In at least one example embodiment, the semiconductor chip 150 may be connected to the package substrate 110 via solder 156. Solder 156 may include, for example, solder balls and solder bumps. In some example embodiments, different from the example illustrated in the figures, the solder 156 may comprise the plurality of solder patterns 40 of the waveguide structure 10, but the example embodiments are not limited thereto.

The waveguide structure 10 according to various embodiments of the present disclosure described in the embodiments of FIGS. 1 to 11 may be applied to the semiconductor package 100 according to the embodiments of FIGS. 12 to 14. The waveguide structure 10 may transmit the RF signal received through interconnector 185 to the integrated circuit 130 and/or the semiconductor chip 150. In some example embodiments, the RF signal received through interconnector 185 may be converted into a transmission signal having a different wavelength than the RF signal, and the transmission signal may be transmitted to the integrated circuit 130 and/or the semiconductor chip 150 via waveguide structure 10.

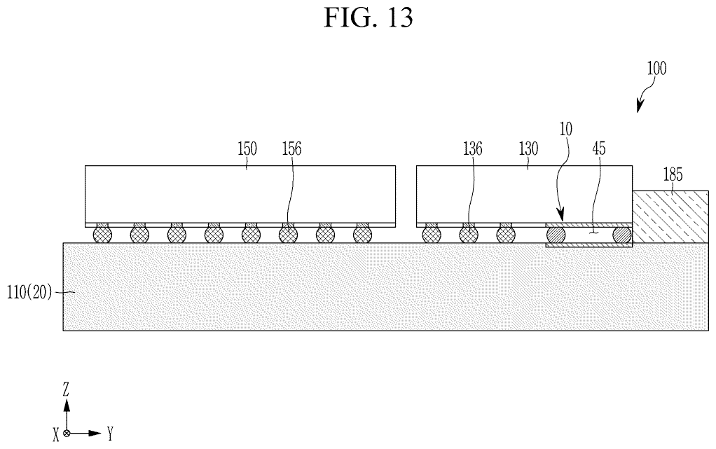

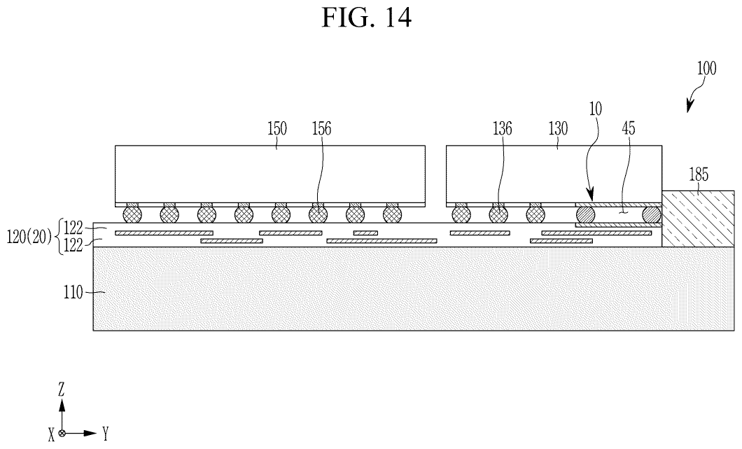

For example, as illustrated in FIG. 12, the package substrate 110 may correspond to the first substrate (see 20 of FIG. 1) and the first wiring (see 21 of FIG. 1) of the waveguide structure 10. In these cases, the RF signal received through the interconnector 185 may be transmit through the waveguide region 45 of the waveguide structure 10 to the integrated circuit 130 and/or the semiconductor chip 150. As another example, as illustrated in FIG. 13, the package substrate 110 may correspond to the first substrate (see 20 of FIG. 1) and the first wiring (see 21 of FIG. 1) of the waveguide structure 10, and at least a portion of the integrated circuit 130 may correspond to the second substrate (see 30 of FIG. 1) and the second wiring (see 31 of FIG. 1) of the waveguide structure 10. Additionally, solder 136 for connecting the integrated circuit 130 to the package substrate 110 may be formed of a plurality of solder patterns (see 40 of FIG. 1) of the waveguide structure 10. As another example, as illustrated in FIG. 14, at least a portion of the redistribution structure 120 may correspond to the first substrate (see 20 of FIG. 1) and the first wiring (see 21 of FIG. 1) of the waveguide structure 10.

It should be understood that the semiconductor package 100 according to at least one example embodiment may include more components in addition to the components described above, but for convenience of explanation, only major components are introduced herein.

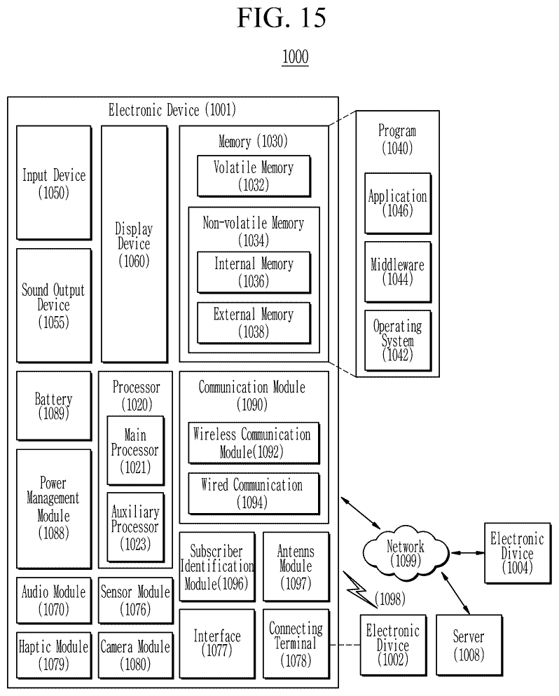

FIG. 15 is a block diagram of an electronic device according to at least one example embodiment.

Referring to FIG. 15, in a network environment according to at least one example embodiment, an electronic device 1001 may communicate with an electronic device 1002 via a first network 1098, or with an electronic device 1004 or a server 1008 via a second network 1099.

According to at least one example embodiment, electronic device 1001 may communicate with electronic device 1004 via server 1008. According to at least one example embodiment, the electronic device 1001 may include a processor 1020, a memory 1030, an input device 1050, an audio output device 1055, a display device 1060, an audio module 1070, a sensor module 1076, an interface 1077, a haptic module 1079, a camera module 1080, a power management module 1088, a battery 1089, a communication module 1090, a subscriber identification module 1096, or an antenna module 1097.

In at least one example embodiment, the electronic device 1001 may have at least one of the components omitted (e.g., the display device 1060 or the camera module 1080), or one or more other components added. In some example embodiments, some of the components may be implemented as a single integrated circuit. For example, a sensor module (1076, e.g., a fingerprint sensor, an iris sensor, or an ambient light sensor) may be implemented embedded in a display device (1060, e.g., a display).

The processor 1020 may, for example, be configured to execute software (e.g., a program 1040) to control at least one other component (e.g., a hardware or software component) of the electronic device 1001 connected to the processor 1020 and perform various data processing or operations. In some example embodiments, as at least part of data processing or calculation, the processor 1020 may load a command or data received from another component (e.g., a sensor module 1076 or a communication module 1090) into the volatile memory 1032, process the command or data stored in the volatile memory 1032, and store result data in the non-volatile memory 1034. According to at least one example embodiment, the processor 1020 may include a main processor (1021, e.g., a central processing unit or application processor) and a secondary processor (1023, e.g., a graphics processing unit, an image signal processor, a sensor hub processor, or a communications processor) that may operate independently or in conjunction therewith. Additionally and/or alternatively, the auxiliary processor 1023 may be configured to use lower power than the main processor 1021, or to be specialized for a specified function.

The auxiliary processor 1023 may be implemented separately from the main processor 1021, or as part of the main processor 1021. The auxiliary processor 1023 may be configured to control at least a portion of functions or states associated with at least one of the components of the electronic device 1001 (e.g., the display device 1060, the sensor module 1076, and/or the communication module 1090), for example, on behalf of the main processor 1021 while the main processor 1021 is in an inactive (e.g., sleep) state, or together with the main processor 1021 while the main processor 1021 is in an active (e.g., application running) state. In at least one example embodiment, the auxiliary processor (1023, e.g., an image signal processor or a communications processor) may be implemented as part of another functionally related component (e.g., a camera module 1080 or a communications module 1090).

The memory 1030 may store various data used by at least one component of the electronic device 1001 (e.g., the processor 1020 or the sensor module 1076). The data may include, for example, input data or output data for software (e.g., program 1040) and instructions associated therewith. Memory 1030 may include volatile memory 1032 or non-volatile memory 1034.

The program 1040 may be stored as software in the memory 1030 and may include, for example, an operating system 1042, middleware 1044 or an application 1046. The input device 1050 may receive commands or data from outside of the electronic device 1001 (e.g., a user) to be used by a component of the electronic device 1001 (e.g., a processor 1020).

The input device 1050 may be configured to receive an input, e.g., from a user, and may include, for example, a mouse, a keyboard, a touchpad, and/or the like.

The audio output device 1055 may be configured to output an audio signal to the outside of the electronic device 1001. The audio output device 1055 may include, for example, a speaker or a receiver. The speaker may be used for general purposes such as playing multimedia or recordings, and the receiver may be used to receive incoming calls. Depending on the embodiment, the receiver may be implemented separately from the speaker, or as part of the speaker.

The display device 1060 may be configured to visually present information to an external party (e.g., a user) of the electronic device 1001. The display device 1060 may include, for example, a display, a holographic device, or a projector and control circuitry for controlling the device. According to at least one example embodiment, the display device 1060 may include touch circuitry configured to detect a touch, or sensor circuitry (e.g., a pressure sensor) configured to measure a magnitude of a force generated by a touch.

The audio module 1070 may be configured to convert sound into electrical signals, or vice versa. According to at least one example embodiment, the audio module 1070 may acquire sound through the input device 1050, or output sound through the audio output device 1055, or an external electronic device (e.g., electronic device 1002) (e.g., speaker or headphone) directly or wirelessly connected to the electronic device 1001. The audio module 1070 may include, for example, a microphone and/or a speaker.

The sensor module 1076 may be configured to detect an operating state (e.g., power or temperature) of the electronic device 1001, or an external environmental state (e.g., user state), and generate an electrical signal or data value corresponding to the detected state. According to at least one example embodiment, the sensor module 1076 may include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, or an ambient light sensor.

Interface 1077 may be configured to support one or more designated protocols that may be used to allow electronic device 1001 to connect directly or wirelessly with an external electronic device (e.g., electronic device 1002). Depending on the example embodiment, the interface 1077 may include, for example, a high definition multimedia interface (HDMI), a universal serial bus (USB) interface, an SD card interface, or an audio interface.

The connection terminal 1078 may include a connector configured to physically connect the electronic device 1001 to an external electronic device (e.g., the electronic device 1002). Depending on the embodiment, the connection terminal 1078 may include, for example, an HDMI connector, a USB connector, an SD card connector, or an audio connector (e.g., a headphone connector).

The haptic module 1079 may be configured to convert electrical signals into mechanical stimuli (e.g., vibration or movement) or electrical stimuli that may be perceived by a user through a tactile or kinesthetic sense. In some example embodiments, the haptic module 1079 may include, for example, a motor, a piezoelectric element, or an electrical stimulation device.

The camera module 1080 may be configured to convert optical signals to electricals. For example, the camera module 1080 may be configured to capture still images and videos. According to at least one example embodiment, the camera module 1080 may include one or more lenses, image sensors, image signal processors, or flashes.

The power management module 1088 may be configured to manage power supplied to the electronic device 1001. In some example embodiments, the power management module 1088 may be implemented as at least part of a power management integrated circuit (PMIC), for example.

Battery 1089 may be configured to power at least one component of electronic device 1001. According to at least one example embodiment, the battery 1089 may include, for example, a non-rechargeable primary battery, a rechargeable secondary battery, or a fuel cell.

The communication module 1090 may be configured to support establishment of a direct (e.g., wired) communication channel or wireless communication channel between the electronic device 1001 and an external electronic device (e.g., electronic device 1002, electronic device 1004, or server 1008), and performance of communication through the established communication channel. The communication module 1090 may include one or more communication processors that operate independently of the processor (e.g., application processor 1020) and support direct (e.g., wired) or wireless communications.

According to at least one example embodiment, the communication module 1090 may include a wireless communication module (1092, for example, a cellular communication module, a short-range wireless communication module, or a global navigation satellite system (GNSS) communication module) or a wired communication module (1094, for example, a local area network (LAN) communication module, or a power line communication module). The communication module 1090 may communicate with an external electronic device via a first network (1098, for example, a short-range communication network such as Bluetooth, WiFi direct or IrDA (infrared data association)) or the second network (1099, for example, a long-range communication network such as a cellular network, the Internet, or a computer network (e.g., a LAN or WAN)). The communication modules 1092 and 1094 may be integrated into a single component (e.g., a single chip), or implemented as multiple separate components (e.g., multiple chips).

The wireless communication module 1092 may be configured to identify and authenticate the electronic device 1001 within a communication network, such as the first network 1098 or the second network 1099, using subscriber information (e.g., International Mobile Subscriber Identity (IMSI)) stored in the subscriber identification module 1096.

The antenna module 1097 may be configured to transmit or receive signals or power to or from an external source (e.g., an external electronic device). According to at least one example embodiment, the antenna module 1097 may include one or more antennas. At least one antenna suitable for a communication method used in a communication network, such as first network 1098 or the second network 1099, may be selected, for example, by the communication module 1090. A signal or power may be transmitted or received between the communication module 1090 and an external electronic device via at least one selected antenna.

At least some of the components may be connected to each other and exchange signals (e.g., commands or data) with each other via a communication method between peripheral devices (e.g., a bus, GPIO (general purpose input and output), SPI (serial peripheral interface), or MIPI (mobile industry processor interface)). According to at least one example embodiment, commands or data may be transmitted or received between the electronic device 1001 and an external electronic device 1004 via a server 1008 connected to a second network 1099.

Electronic devices 1002 and 1004 may each be the same or a different type of device as electronic device 1001. According to at least one example embodiment, all or part of the operations executed on the electronic device 1001 may be executed on one or more of the external electronic devices (1002, 1004, or 1008). For example, if the electronic device 1001 is to perform a function or service automatically, or in response to a request from a user or another device, the electronic device 1001 may, instead of executing the function or service itself, or in addition, request one or more external electronic devices to perform at least a portion of the function or service. One or more external electronic devices that receive the request may execute at least a portion of the requested function or service, or an additional function or service related to the request, and transmit the result of the execution to the electronic device 1001. The electronic device 1001 may provide the result, either as is or additionally processed, as at least part of a response to the request. For this purpose, for example, cloud computing, distributed computing, or client-server computing technologies may be used.

The waveguide structure 10 according to the various example embodiments of the present disclosure described may implement a signal transmission path necessary for communication between electronic devices 1001, 1002, and 1004, communication between at least one of various components included in the electronic device 1001 and another one, etc. For example, the waveguide structure 10 may implement a signal path that transmits a signal transmitted from the connection terminal 1078 and/or the antenna module 1097 to at least one of various components included in the electronic device 1001, but example embodiments are not limited thereto.

Although some example embodiments have been described above, the present invention is not limited thereto, and various modifications may be made within the scope of the claims, the detailed description of the invention, and the attached drawings, which also fall within the scope of the present invention.

What is claimed is:

1. A waveguide structure comprising:
a first substrate;
a first wiring on the first substrate;
a second wiring spaced apart from the first substrate and the first wiring such that the second wiring is opposing the first wiring; and
a plurality of solder patterns between the first wiring and the second wiring, the plurality of solder patterns spaced apart from each other in a first direction, and defining a waveguide region between the first wiring and the second wiring such that the waveguide region extends along the first direction.

2. The waveguide structure of claim 1, wherein the plurality of solder patterns include:
a plurality of first solder patterns spaced apart from each other in the first direction, and
a plurality of second solder patterns spaced apart from each other in the first direction,
wherein the plurality of first solder patterns and the plurality of second solder patterns are spaced apart in a second direction, the second direction intersecting the first direction, and
the waveguide region is further defined by the plurality of first solder patterns and the plurality of second solder patterns.

3. The waveguide structure of claim 2, wherein a distance between the plurality of first solder patterns and the plurality of second solder patterns in the second direction is greater than or equal to a distance between the first wiring and the second wiring.

4. The waveguide structure of claim 2, wherein a distance between the plurality of first solder patterns and the plurality of second solder patterns in the second direction is greater than or equal to a thickness of the plurality of first solder patterns.

5. The waveguide structure of claim 2, wherein a distance between the plurality of first solder patterns in the first direction is greater than 0 millimeters (mm) and less than or equal to 1.95 mm.

6. The waveguide structure of claim 1, wherein the plurality of solder patterns are in contact with an upper surface of the first wiring and a lower surface of the second wiring.

7. The waveguide structure of claim 6, wherein the first wiring and the second wiring extend in the first direction.

8. The waveguide structure of claim 1, wherein the first wiring and the second wiring are configured to receive a ground voltage.

9. The waveguide structure of claim 8, wherein the plurality of solder patterns are electrically connected to the first wiring and the second wiring.

10. The waveguide structure of claim 1, wherein the first wiring defines a lower surface of the waveguide region, and
the second wiring defines an upper surface of the waveguide region.

11. The waveguide structure of claim 1, further comprising:
a first insulating layer on an upper surface of the first wiring, and
a second insulating layer on a lower surface of the second wiring;
wherein the plurality of solder patterns penetrate the first insulating layer and the second insulating layer such that the plurality of solder patterns are electrically connected to the first wiring and the second wiring.

12. The waveguide structure of claim 11, further comprising:
a first dielectric layer on the first wiring, and
a first pad on the first dielectric layer and electrically connected to the first wiring,
wherein the plurality of solder patterns are electrically connected to the first pad.

13. The waveguide structure of claim 12, wherein
the first wiring defines a lower surface of the waveguide region, and
the second wiring defines an upper surface of the waveguide region.

14. The waveguide structure of claim 12, further comprising:
a second dielectric layer on the lower surface of the second wiring, and
a second pad on a lower surface of the second dielectric layer and electrically connected to the second wiring;
wherein the plurality of solder patterns are electrically connected to the second pad.

15. The waveguide structure of claim 1, wherein the waveguide region is configured to transmit a radio frequency (RF) signal having a millimeter wave (mmWave) band in the first direction.

16. A waveguide structure comprising:
a first substrate;
a first wiring on the first substrate, the first wiring extending in a first direction;
a second wiring spaced apart from the first substrate and the first wiring, the second wiring extending in the first direction and opposing the first wiring; and
a plurality of solder patterns electrically connected to the first wiring and the second wiring and spaced apart from each other in the first direction and in a second direction intersecting the first direction such that the plurality of solder patterns define a waveguide region extending along the first direction between the first wiring and the second wiring.

17. The waveguide structure of claim 16, wherein the first wiring and the second wiring are configured to receive a ground voltage.

18. The waveguide structure of claim 16, wherein the plurality of solder patterns include:
a plurality of first solder patterns spaced apart from each other in the first direction, and
a plurality of second solder patterns spaced apart from each other in the first direction,
wherein the plurality of first solder patterns and the plurality of second solder patterns are spaced apart in the second direction, and
the plurality of first solder patterns and the plurality of second solder patterns define opposite sides of the waveguide region.

19. The waveguide structure of claim 18, wherein a distance between the plurality of first solder patterns and the plurality of second solder patterns in the second direction is greater than or equal to a distance between the first wiring and the second wiring.

20. A semiconductor package comprising:
a first substrate;
an interconnector on the first substrate and configured to receive an RF signal;
an integrated circuit mounted on the first substrate and spaced apart from the interconnector in a first direction;
a waveguide structure configured to transmit the RF signal from the interconnector and to the integrated circuit;
a semiconductor chip mounted on the first substrate and spaced apart from the waveguide structure,
wherein the waveguide structure includes
a first wiring on the first substrate,
a second wiring spaced apart from the first wiring and the first substrate, and
a plurality of solder patterns between the first wiring and the second wiring, the plurality of solder patterns spaced apart from each other in the first direction, and defining a waveguide region between the first wiring and the second wiring such that the waveguide region extends along the first direction.
